(19) United States
(12) Patent Application Publication
(10) Pub. No.: US 2026/0086382 A1
(43) Pub. Date: Mar. 26, 2026

(54) DISPLAY SYSTEM

(71) Applicant: AUO Corporation, Hsinchu City (TW)

(72) Inventors: Sing-Ru Lin, Hsinchu City (TW); Ying-Chieh Chen, Hsinchu City (TW); Yung-Hsiang Lan, Hsinchu City (TW); Shih-Chi Fan-Jiang, Hsinchu City (TW); Yung-Chih Chen, Hsinchu City (TW)

(73) Assignee: AUO Corporation, Hsinchu City (TW)

(21) Appl. No.: 19/340,851

(22) Filed: Sep. 25, 2025

(30) Foreign Application Priority Data
Sep. 26, 2024 (TW) 113136778

(51) Int. Cl. G02B 27/28; H10H 29/852; H10H 29/855

(52) U.S. Cl. CPC G02B 27/281; H10H 29/852; H10H 29/855

(57) ABSTRACT

Disclosed is a display system including a display panel, a camera module, a quarter wave plate, a linear polarizer, an optical layer and a cover layer. The camera module is disposed on one side of the display panel and disposed in a display area of the display panel. The quarter wave plate is disposed on the other side of the display panel opposite to the camera module. The quarter wave plate is disposed between the display panel and the linear polarizer. The optical layer is disposed between the linear polarizer and the cover layer.

### CROSS-REFERENCE TO RELATED APPLICATION

This application claims the priority benefit of Taiwan application serial no. 113136778, filed on Sep. 26, 2024. The entirety of the above-mentioned patent application is hereby incorporated by reference herein and made a part of this specification.

### BACKGROUND

### Technical Field

The present disclosure relates to a display system.

### Description of Related Art

Current smartphones or tablet devices are typically equipped with camera modules for purposes such as photography and video conferencing. To reduce the thickness of the bezel of the device, it is possible to further integrate the camera module, known as Under Display Camera (UDC) technology, beneath the display. This technology involves positioning a non-display area or a blank area within a display area of the screen, and placing the camera module in this non-display area/blank area. However, the presence of the non-display area/blank area may affect the aesthetic appeal of the device, which many consumers find unacceptable.

Another type of UDC technique utilizes the light transmittance of the display panel, opting to place the camera module within the display area. For instance, if the screen is a micro light-emitting diode display (Micro LED Display), metal blocking layers and side shields may be positioned on the micro light-emitting diode elements of the display to block backlight leakage and side light leakage from the micro light-emitting diode elements. However, such arrangements still fail to effectively mitigate the reflection problem caused by the cover layer at the forefront of the display system. An alternative improved technique involves placing a circular polarizer (CPL) and a haze layer (such as haze OCA) between the camera module and the display panel, or between the display panel and the cover layer, to reduce reflection issues caused by the cover layer. Nonetheless, the configuration of a circular polarizer and a haze layer results in adverse effects, such as diminished camera module performance and a significant reduction in display panel brightness.

### SUMMARY

The present disclosure provides a display system that may provide good capture effects and improved viewing effects while having a good appearance.

An embodiment of the present disclosure provides a display system that includes a display panel, a camera module, a quarter wave plate, a linear polarizer, an optical layer, and a cover layer. The camera module is disposed on one side of the display panel and is disposed within a display area of the display panel. The quarter wave plate is disposed on the other side of the display panel opposite to the camera module. The quarter wave plate is disposed between the display panel and the linear polarizer. The optical layer is disposed between the linear polarizer and the cover layer.

Based on the above, in an embodiment of the present disclosure, an optical film assembly of the display system is designed such that: the quarter wave plate is disposed on the other side of the display panel opposite to the camera module, the quarter wave plate is disposed between the display panel and the linear polarizer, and the optical layer is disposed between the linear polarizer and the cover layer. Therefore, the display light emitted by the display panel may be blocked by the optical film assembly after being reflected by the cover layer without entering the camera module, and ambient light may also be blocked by the optical film assembly after being reflected by the display panel or the camera module without being emitted from the cover layer, thereby enabling the camera module to clearly capture required images and providing the display system with improved viewing effects while having a good appearance.

### BRIEF DESCRIPTION OF THE DRAWINGS

FIG. 1A is a schematic view of a display system according to a first embodiment of the present disclosure.

FIG. 1B is a schematic view of an effect of an exit light ELC and an incident light ILC transmitted in the display system in FIG. 1A.

FIG. 2A is a schematic view of a display system according to a second embodiment of the present disclosure.

FIG. 2B is a schematic view of the effect of the exit light ELC and the incident light ILC transmitted in the display system in FIG. 2A.

FIG. 3A is a schematic view of a display system according to a third embodiment of the present disclosure.

FIG. 3B is a schematic view of the effect of the exit light ELC and the incident light ILC transmitted in the display system in FIG. 3A.

### DESCRIPTION OF THE EMBODIMENTS

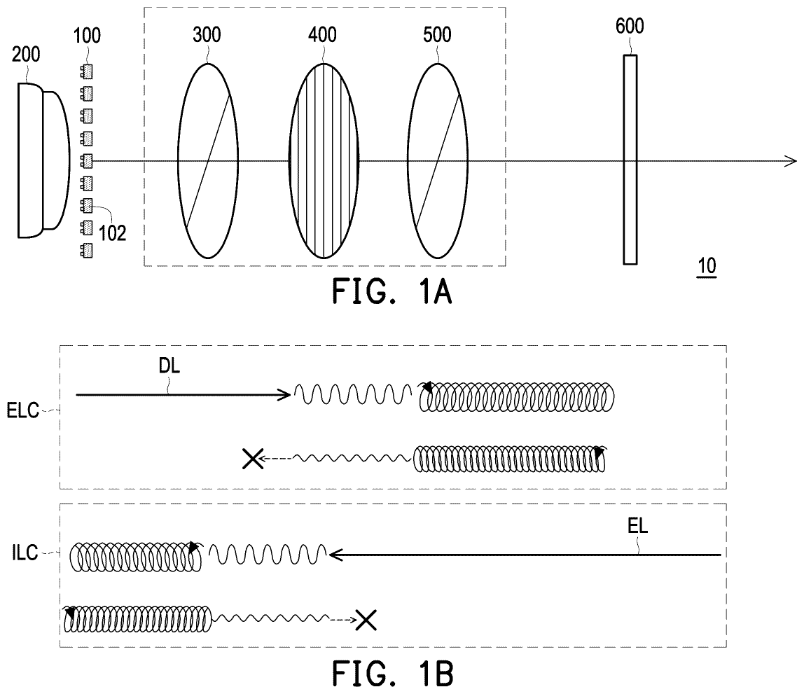

FIG. 1A is a schematic view of a display system according to a first embodiment of the present disclosure. Please refer to FIG. 1A, an embodiment of the present disclosure provides a display system 10, which includes a display panel 100, a camera module 200, a quarter wave plate 300, a linear polarizer 400, an optical layer 500, and a cover layer 600. The camera module 200 is disposed on one side of the display panel 100 and is disposed within a display area of the display panel 100. The quarter wave plate 300 is disposed on the other side of the display panel 100 opposite to the camera module 200. The quarter wave plate 300 is disposed between the display panel 100 and the linear polarizer 400. The optical layer 500 is disposed between the linear polarizer 400 and the cover layer 600.

In this embodiment, the display panel 100 includes multiple light-emitting elements 102. A portion of the light-emitting elements 102 are disposed within a sensing area of the camera module 200. The light-emitting elements 102 may be micro light-emitting diodes (micro LEDs), mini LEDs, or other suitable light sources.

In this embodiment, the camera module 200 may be a complementary metal-oxide semiconductor (CMOS), a charge coupled device (CCD), or other optical sensors, but the present disclosure is not limited thereto. In addition, the camera module 200 may also include a light collecting lens. The light collecting lens includes, for example, a combination of one or more optical lenses with refractive power, such as various combinations of non-planar lenses including biconcave lenses, biconvex lenses, meniscus lenses, convex-concave lenses, plano-convex lenses, and plano-concave lenses.

In this embodiment, the cover layer 600 may be a plastic cover plate, a glass cover plate, a touch panel, or other elements disposed at the outermost layer of the display system 10.

FIG. 1B is a schematic view of an effect of an exit light ELC and an incident light ILC transmitted in the display system in FIG. 1A. Please refer to both FIG. 1A and FIG. 1B simultaneously. In this embodiment, the optical layer 500 is (another) quarter wave plate. As shown in FIG. 1B, in the case of the exit light ELC, a display light DL emitted by the display panel 100 first passes through the quarter wave plate 300, and the display light DL is not affected. Subsequently, the display light DL sequentially passes through the linear polarizer 400 and the optical layer 500, and is sequentially changed to a linear polarized light (for example, FIG. 1B illustrates the linear polarized light in a vertical direction) and a circular polarized light. The circular polarized light may be a right-handed/left-handed polarized light. When this circular polarized light is transmitted to the cover layer 600, a portion of the display light DL is reflected by the cover layer 600 to form the left-handed/right-handed polarized light. The left-handed/right-handed polarized light passing through the optical layer 500 will be changed to the linear polarized light (for example, FIG. 1B illustrates the linear polarized light in a horizontal direction). However, the linear polarized light (in horizontal direction) will be blocked by the linear polarizer 400 (in vertical direction) and will not enter the camera module 200.

Conversely, in the case of the incident light ILC, an ambient light EL first passes through the optical layer 500, and the ambient light EL is not affected. Subsequently, the ambient light EL sequentially passes through the linear polarizer 400 and the quarter wave plate 300, and is sequentially changed to the linear polarized light (for example, FIG. 1B illustrates the linear polarized light in the vertical direction) and the circular polarized light. The circular polarized light may be a right-handed/left-handed polarized light. When the circular polarized light is transmitted to the display panel 100 or the camera module 200, a portion of the ambient light EL will be reflected by the display panel 100 or the camera module 200 to form the left-handed/right-handed polarized light. The left-handed/right-handed polarized light passing through the quarter wave plate 300 will be changed to the linear polarized light (for example, FIG. 1B illustrates the linear polarized light in the horizontal direction). However, the linear polarized light (in horizontal direction) will be blocked by the linear polarizer 400 (in vertical direction) and will not be emitted from the cover layer 600.

Based on the above, in an embodiment of the present disclosure, the display system 10 includes the display panel 100, the camera module 200, the optical film assembly, and the cover layer 600. The optical film assembly includes the quarter wave plate 300, the linear polarizer 400, and the optical layer 500. The quarter wave plate 300 is disposed on the other side of the display panel 100 opposite to the camera module 200. The quarter wave plate 300 is disposed between the display panel 100 and the linear polarizer 400. The optical layer 500 is disposed between the linear polarizer 400 and the cover layer 600. As shown in FIG. 1B, the display light DL emitted by the display panel 100 may be blocked by the optical film assembly after being reflected by the cover layer 600 without entering the camera module 200, and the ambient light EL is also blocked by the optical film assembly after being reflected by the display panel 100 or the camera module 200 without being emitted from the cover layer 600. Therefore, the optical film assembly may block the reflected light inside the display system 10 so that the camera module 200 may clearly capture required images. Moreover, the ambient light EL is not emitted from the display system 10 after being reflected within the display system 10, thereby providing an enhanced viewing experience with the display system 10.

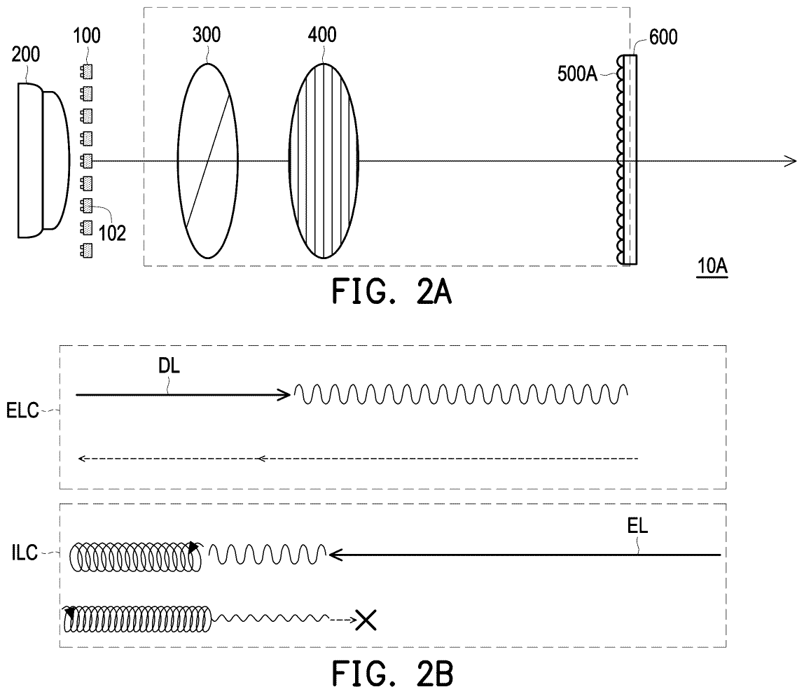

FIG. 2A is a schematic view of a display system according to a second embodiment of the present disclosure. FIG. 2B is a schematic view of the effect of the exit light ELC and the incident light ILC transmitted in the display system in FIG. 2A. Please refer to FIG. 2A and FIG. 2B simultaneously, a display system 10A is similar to the display system 10 of FIG. 1A, with main differences as follows. In this embodiment, an optical layer 500A is a moth-eye structure, and the optical layer 500A is directly disposed on the cover layer 600.

As shown in FIG. 2B, in the case of the exit light ELC, the display light DL emitted by the display panel 100 first passes through the quarter wave plate 300, and the display light DL is not affected. Next, the display light DL passes through the linear polarizer 400 and is changed to the linear polarized light (for example, FIG. 1B illustrates the linear polarized light in the vertical direction). When the linear polarized light is transmitted to the optical layer 500A, the optical layer 500A with the moth-eye structure may provide anti-reflection effects and reduce the influence of the reflected display light DL on the camera module 200 for capturing.

Conversely, the display system 10A in the case of the incident light ILC is the same as the display system 10 in FIG. 1B in the case of the incident light ILC, and will not be described again here. Therefore, in an embodiment of the present disclosure, the display system 10A may also provide the camera module 200 with good capturing effects.

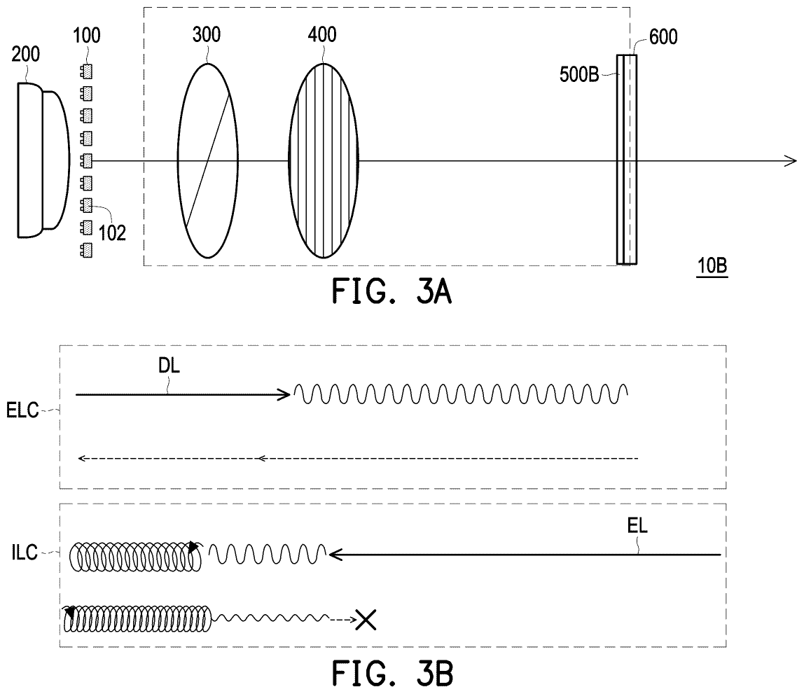

FIG. 3A is a schematic view of a display system according to a third embodiment of the present disclosure. FIG. 3B is a schematic view of the effect of the exit light ELC and the incident light ILC transmitted in the display system in FIG. 3A. Please refer to FIG. 3A and FIG. 3B simultaneously, a display system 10B is similar to the display system 10A of FIG. 2A, with main differences as follows. In this embodiment, an optical layer 500B is an anti-reflection layer, and the optical layer 500B is directly disposed on the cover layer 600.

As shown in FIG. 3B, the display system 10B in the case of the exit light ELC and the case of the incident light ILC is the same as the display system 10A in FIG. 2B, and will not be described again here. Therefore, in an embodiment of the present disclosure, the display system 10B may also provide the camera module 200 with good capturing effects.

In summary, in an embodiment of the present disclosure, the display system includes the display panel, the camera module, the optical film assembly, and the cover layer. The optical film assembly includes the quarter wave plate, the linear polarizer, and the optical layer. The quarter wave plate is disposed on the other side of the display panel opposite to the camera module, the quarter wave plate is disposed between the display panel and the linear polarizer, and the optical layer is disposed between the linear polarizer and the cover layer. Therefore, the display light emitted by the display panel may be blocked by the optical film assembly after being reflected by the cover layer without entering the camera module, and the ambient light may also be blocked by the optical film assembly after being reflected by the display panel or the camera module without being emitted from the cover layer, thereby enabling the camera module to clearly capture the required images.

What is claimed is:

1. A display system, comprising:
a display panel;
a camera module, disposed on one side of the display panel, and disposed within a display area of the display panel;
a quarter wave plate, disposed on the other side of the display panel opposite to the camera module;
a linear polarizer, wherein the quarter wave plate is disposed between the display panel and the linear polarizer;
an optical layer; and
a cover layer, wherein the optical layer is disposed between the linear polarizer and the cover layer.

2. The display system as described in claim 1, wherein the optical layer is a quarter wave plate.

3. The display system as described in claim 1, wherein the optical layer is a moth-eye structure.

4. The display system as described in claim 3, wherein the optical layer is directly disposed on the cover layer.

5. The display system as described in claim 1, wherein the optical layer is an anti-reflection layer.

6. The display system as described in claim 5, wherein the optical layer is directly disposed on the cover layer.

7. The display system as described in claim 1, wherein the display panel comprises a plurality of light-emitting elements, a portion of the light-emitting elements are disposed within a sensing area of the camera module.

8. The display system as described in claim 7, wherein the plurality of light-emitting elements are micro light-emitting diodes (LEDs) or mini LEDs.

9. A display system, comprising:
a display panel, comprising a plurality of light-emitting elements;
a camera module, disposed on one side of the display panel, and disposed within a display area of the display panel;
a quarter wave plate, disposed on the other side of the display panel opposite to the camera module;
a linear polarizer, wherein the quarter wave plate is disposed between the display panel and the linear polarizer;
an optical layer; and
a cover layer, wherein the optical layer is disposed between the linear polarizer and the cover layer,
wherein the plurality of light-emitting elements are micro LEDs or mini LEDs.

10. The display system as described in claim 9, wherein the optical layer is a quarter wave plate.

11. The display system as described in claim 9, wherein the optical layer is a moth-eye structure.

12. The display system as described in claim 11, wherein the optical layer is directly disposed on the cover layer.

13. The display system as described in claim 9, wherein the optical layer is an anti-reflection layer.

14. The display system as described in claim 13, wherein the optical layer is directly disposed on the cover layer.

15. The display system as described in claim 9, wherein a portion of the plurality of light-emitting elements are disposed within a sensing area of the camera module.
